(19) United States
(12) Patent Application Publication
(10) Pub. No.: US 2013/0026629 A1
(43) Pub. Date: Jan. 31, 2013

(54) SEMICONDUCTOR DEVICE, SEMICONDUCTOR DEVICE UNIT, AND SEMICONDUCTOR DEVICE PRODUCTION METHOD

(71) Applicant: Panasonic Corporation, Osaka (JP)

(72) Inventor: Sumiaki NAKANO, Nara (JP)

(73) Assignee: Panasonic Corporation, Osaka (JP)

(21) Appl. No.: 13/646,067

(22) Filed: Oct. 5, 2012

Related U.S. Application Data
(63) Continuation of application No. PCT/JP2011/003462, filed on Jun. 17, 2011.

(30) Foreign Application Priority Data
Sep. 16, 2010 (JP) 2010-207395

(51) Int. Cl. H01L 23/48; H01L 21/768

(52) U.S. Cl. 257/737; 438/613; 257/E23.01; 257/E21.589

(57) ABSTRACT

An example of a semiconductor device according to the present invention includes: a protective film (1) which has an opening to expose a part of the surface of an electrode pad (4) and covers the surface of the electrode pad (4) excluding the opening; and a bump (6) which is electrically connected with the electrode pad (4) through the opening of the protective film (1) and has a part exposed outside within the area of the electrode pad (4), wherein probe marks (7) are formed by a probe brought into contact with the electrode pad (4) for electrical characteristic inspection, and the probe marks (7) are positioned within a region where the protective film (1) is formed and are covered by the protective film (1).

### TECHNICAL FIELD

The present invention relates to a semiconductor device including an external connection terminal such as a projecting electrode (what is called a bump), a semiconductor device unit including a mounting substrate with the semiconductor device mounted thereon, and a production method for the semiconductor device.

### BACKGROUND ART

In semiconductor device packaging technology, a bump is formed on a semiconductor chip in, for example, chip size package or chip scale package (CSP) and flip-chip package. A semiconductor device, on which a bump is to be formed, typically includes a passivation film, an under barrier metal (UBM) to which the bump is to be bonded, and a protective film for protecting the outermost surface of a semiconductor chip. The under barrier metal is provided to increase the bond strength between an electrode pad and the bump formed thereon. Typical methods for forming a bump on an under barrier metal include printing, plating, and bump material mounting.

A bump on a semiconductor chip is used to electrically and mechanically connect the semiconductor chip to a resin substrate with the semiconductor chip mounted thereon.

Prior to mounting the semiconductor chip on the resin substrate, inspection has to be performed to confirm electrical characteristics of circuit function of the semiconductor chip. As a method for performing the inspection, a probe is brought into contact with the bump to confirm the electrical characteristics. However, in the inspection method using a probe, probe marks having different sizes are formed at points with which the probe comes into contact. Therefore, when the electrical characteristics are inspected by bringing the probe into contact with the bump, probe marks having different sizes are formed on the surface of the bump. The probe marks on the surface of the bump may decrease the reliability of connection between the semiconductor chip and the resin substrate. For example, the probe marks may cause voids in the bump after the semiconductor chip and the resin substrate are connected to each other. The effects of the probe marks become more apparent with a size reduction of the bump.

Meanwhile, bump scraps may stick to the probe brought into contact with the bump. Therefore, the probe needs to be cleansed. It is known that bump scraps noticeably stick to the probe particularly when the bump is made of solder.

Therefore, the electrical characteristic inspection is performed by bringing the probe into contact with the electrode pad before forming the bump. Thereafter, an under barrier metal and the bump are formed. This method can solve the above-described problems in which probe marks are formed on the surface of the bump and bump scraps stick to the probe.

However, when the probe mechanically contacts the electrode pad which is provided on the active face of the semiconductor chip and is used for communicating electrical signals with the outside, probe impressions are left on the surface of the electrode pad. Therefore, the under barrier metal is formed on the electrode pad with probe marks thereon, and the bump is formed on the under barrier metal. As a result, the bond strength between the electrode pad and the bump via the under barrier metal is disadvantageously reduced, thereby causing poor connection and shape variation of the bump.

FIG. 21 is a cross-sectional view for explaining effects of probe marks formed on the surface of the electrode pad.

In FIG. 21, reference numeral 1 denotes a protective film, reference numeral 2 denotes an under barrier metal, reference numeral 3 denotes a protective film, reference numeral 4 denotes an electrode pad, reference numeral 5 denotes a silicon substrate, reference numeral 6 denotes a bump, and reference numeral 7 denotes a probe mark.

The electrode pad 4 is formed on the silicon substrate 5. The first protective film 3 protects the silicon substrate 5 and the peripheral edge of the electrode pad 4. The second protective film 1 has an opening to expose a part of the surface of the electrode pad 4 and covers the first protective film 3 and the surface of the electrode pad 4 ranging from the peripheral edge of the opening to the first protective film 3. Therefore, the peripheral edge of the electrode pad 4 and the surface of the silicon substrate 5 excluding the area of the electrode pad 4 are doubly covered with the first protective film 3 and the second protective film 1.

The under barrier metal 2 is formed on the surface of the region of the electrode pad 4 exposed from the second protective film 1. The bump 6 is formed on the surface of the region of the electrode pad 4 exposed from the second protective film 1 via the under barrier metal 2. The probe mark 7 is formed by a probe brought into contact with the electrode pad 4 during electrical characteristic inspection.

As illustrated in FIG. 21, when the probe mark 7 is formed on the region of the electrode pad 4 exposed from the second protective film 1, the shape of the under barrier metal 2 on the electrode pad 4 is directly affected by the shape of the probe mark 7. Therefore, shape defects occur on the under barrier metal 2. In other words, shape defects occur in the bonded surface of the under barrier metal 2 and the bump 6. Thus, the bond strength between the electrode pad 4 and the bump 6 is reduced via the under barrier metal 2, thereby causing poor connection of the bump. Further, in the case where the probe mark 7 is formed close to the second protective film 1, the bump material may flow into the probe mark 7, so that the shape of the bump 6 may be affected by the probe mark 7. That is, the bump shape may be varied.

Hence, it is considerably important to reduce or prevent the effects of the probe mark 7 in forming the bump 6 after electrical characteristic inspection using a probe, for improvement in the reliability of the semiconductor device.

In order to avoid the effects of the probe mark, for example, there has been proposed a method in which the surface of an electrode pad is divided into a probe contact region for a probe to contact and a probe non-contact region excluding the probe contact region, the probe is brought into contact with the probe contact region to perform inspection, an insulating film is formed to cover the electrode pad, an opening is formed in the insulating film to expose the probe non-contact region, a rewiring layer to be connected with the electrode pad via the opening is formed on the insulating film, and a bump is formed on a portion of the rewiring layer outside the area of the electrode pad (for example, see Patent Literature 1).

Further, there has been proposed a technique in which an electrode for probe inspection is provided in addition to an electrode for bump formation, the electrode for probe inspection being to be connected to the electrode for bump formation, thereby preventing a probe from contacting the electrode for bump formation (for example, see Patent Literature 2). This technique enables a bump to be stably formed without being affected by probe impressions.

### CITATION LIST

### Patent Literatures

Patent Literature 1: Japanese Patent Application Laid-Open Publication No. 2010-50224
Patent Literature 2: Japanese Patent Application Laid-Open Publication No. 2001-284383

### SUMMARY OF INVENTION

### Technical Problem

In the conventional technique using the rewiring layer, even in the case where a relatively large probe mark is formed on the surface of the electrode pad in the electrical characteristic inspection of a semiconductor chip, the bump to be connected with the electrode pad via the rewiring layer is formed on the portion outside the area of the electrode pad, thereby obtaining a highly reliable semiconductor device. However, this technique requires the additional step of forming the rewiring layer to avoid the effects of the probe mark. Thus, addition of a complicated process and an area for the rewiring layer are needed. Further, in the case where the rewiring layer is also formed above the probe mark, shape defects occur in the rewiring layer when the height of a part on the electrode pad raised by the probe mark exceeds the thickness of the insulating film covering the electrode pad. Moreover, in the case where the depth of the probe mark reaches the underlayer of the electrode pad, metal diffusion and so on occur in the underlayer of the electrode pad when the part on the electrode pad raised by the probe mark comes into contact with the under barrier metal under the rewiring layer. Thus, the functionality and reliability of the semiconductor device are seriously reduced.

In contrast, in the conventional technique using the electrode for probe inspection, the bump is not affected by the probe mark, so that a highly reliable semiconductor device can be obtained. However, in this technique, the electrode for probe inspection is provided to be put into contact with an inspection probe in addition to the electrode for bump formation, which requires areas for both the electrode for probe inspection and the electrode for bump formation. In addition, the bump has to be large enough to ensure electrical and mechanical connection between a semiconductor chip and a resin substrate. Therefore, spatial constraint is increasingly imposed on this technique with reduction in the size of the semiconductor chip and an electrode pitch.

As shown in FIG. 21, even in the case where the under barrier metal 2 is formed on the probe marks 7, metal diffusion occurs from the under barrier metal 2 to the underlayer of the electrode pad 4 when the depths of the probe marks 7 reach the underlayer of the electrode pad 4. Thus, the functionality and reliability of the semiconductor device are seriously reduced.

In view of the above-described problems, it is desirable that the structure made up of the bump and its surrounding including the electrode pad, the protective films, and the under barrier metal be shaped to reduce or prevent effects of probe marks readily and effectively.

The present invention has been devised to solve the above-described problems, and an object of the present invention is to provide a semiconductor device, a semiconductor device unit, and a semiconductor device production method, according to which the reliability of the semiconductor device can be improved by easily reducing or preventing poor connection of a bump.

### Solution to Problem

A semiconductor device of the present invention includes: a substrate; at least one electrode pad formed on the substrate; a protective film which has an opening to expose a part of the surface of the at least one electrode pad and covers the surface of the at least one electrode pad excluding the opening; and an external connection terminal which is electrically connected with the at least one electrode pad through the opening of the protective film and has a part exposed outside within the area of the at least one electrode pad, wherein at least one probe mark is formed on the at least one electrode pad by a probe brought in contact with the at least one electrode pad for electrical characteristic inspection, and the at least one probe mark is positioned within a region where the protective film is formed or directly under an end of the opening of the protective film and is covered by the protective film.

In the semiconductor device of the present invention, the at least one probe mark is preferably formed outside a region where the external connection terminal is formed, as seen in a plan view.

The semiconductor device of the present invention may further include: an under barrier metal which is formed over the surface of the part of the at least one electrode pad exposed from the opening of the protective film and the protective film around the opening or an under barrier metal which is formed only on the surface of the part of the at least one electrode pad exposed from the opening of the protective film. The external connection terminal is formed on the under barrier terminal.

In the semiconductor device of the present invention, the at least one probe mark is preferably formed in the vicinity of the peripheral edge of the at least one electrode pad.

In the semiconductor device of the present invention, the at least one probe mark may include a plurality of probe marks.

In the semiconductor device of the present invention, the at least one probe mark may include at least two probe marks, and the opening of the protective film may be disposed between the two probe marks, as seen in a plan view.

In the semiconductor device of the present invention, the at least one electrode pad may include a plurality of electrode pads which are arranged in a matrix pattern.

A semiconductor device unit of the present invention includes: one of the above-described semiconductor devices of the present invention; and a mounting substrate on which the semiconductor device is mounted.

A semiconductor device production method of the present invention includes the steps of: forming at least one electrode pad on a substrate; performing electrical characteristic inspection by bringing a probe into contact with the at least one electrode pad; forming a protective film which has an opening to expose a part of the surface of the at least one electrode pad and covers the surface of the at least one electrode pad excluding the opening; and forming an external connection terminal which is electrically connected with the at least one electrode pad through the opening of the protective film and has a part exposed outside within the area of the at least one electrode pad, wherein, in the step of performing the electrical characteristic inspection, at least one probe mark is formed on the at least one electrode pad, and in the step of forming the protective film, the protective film is formed such that the at least one probe mark is positioned within a region where the protective film is formed or directly under an end of the opening of the protective film and is covered by the protective film.

### Advantageous Effects of Invention

According to the present invention, it is possible to reduce or prevent effects of probe marks on the structure including the bump and the surrounding of the bump.

Therefore, poor connection of the bump can be easily reduced or prevented, so that the reliability of the semiconductor device can be improved.

### BRIEF DESCRIPTION OF DRAWINGS

FIG. 1 is a cross-sectional view showing the structure including a bump and the surrounding of the bump of a semiconductor device according to an embodiment of the present invention.

FIG. 2 is a cross-sectional view showing another example of positions of probe marks in the semiconductor device according to the embodiment of the present invention.

FIG. 3 is a planar view illustrating the shape of the opening of a protective film and the positions of the probe marks in the semiconductor device according to the embodiment of the present invention.

FIG. 4 is a planar view illustrating the shape of the opening of the protective film and the positions of the probe marks in the semiconductor device according to the embodiment of the present invention.

FIG. 5 is a planar view illustrating the shape of the opening of the protective film and the positions of the probe marks in the semiconductor device according to the embodiment of the present invention.

FIG. 6 is a planar view illustrating the shape of the opening of the protective film and the positions of the probe marks in the semiconductor device according to the embodiment of the present invention.

FIG. 7 is a planar view illustrating the shape of the opening of the protective film and the positions of the probe marks in the semiconductor device according to the embodiment of the present invention.

FIG. 8 is a planar view illustrating the shape of the opening of the protective film and the positions of the probe marks in the semiconductor device according to the embodiment of the present invention.

FIG. 9 is a planar view illustrating the shape of the opening of the protective film and the positions of the probe marks in the semiconductor device according to the embodiment of the present invention.

FIG. 10 is a planar view illustrating the shape of the opening of the protective film and the positions of the probe marks in the semiconductor device according to the embodiment of the present invention.

FIG. 11 is a planar view illustrating the shape of the opening of the protective film and the positions of the probe marks in the semiconductor device according to the embodiment of the present invention.

FIG. 12 is a cross-sectional view showing another example of the structure including the bump and the surrounding of the bump of the semiconductor device according to the embodiment of the present invention.

FIG. 13 is a cross-sectional view showing another example of the structure including the bump and the surrounding of the bump of the semiconductor device according to the embodiment of the present invention.

FIG. 14 is a planar view illustrating the bumps arranged in a grid-like pattern of the semiconductor device according to the embodiment of the present invention.

FIG. 15 is a cross-sectional view showing the configuration of the principal part of a semiconductor device unit according to the embodiment of the present invention.

FIG. 16 is a cross-sectional view illustrating the step of a semiconductor device production method according to the embodiment of the present invention.

FIG. 17 is a cross-sectional view illustrating the step of the semiconductor device production method according to the embodiment of the present invention.

FIG. 18 is a cross-sectional view illustrating the step of the semiconductor device production method according to the embodiment of the present invention.

FIG. 19 is a cross-sectional view illustrating the step of the semiconductor device production method according to the embodiment of the present invention.

FIG. 20 is a cross-sectional view illustrating the step of the semiconductor device production method according to the embodiment of the present invention.

FIG. 21 is a cross-sectional view for explaining effects of probe marks formed on the surface of the electrode pad.

### DESCRIPTION OF EMBODIMENTS

The following will describe an embodiment of the present invention with reference to the accompanying drawings.

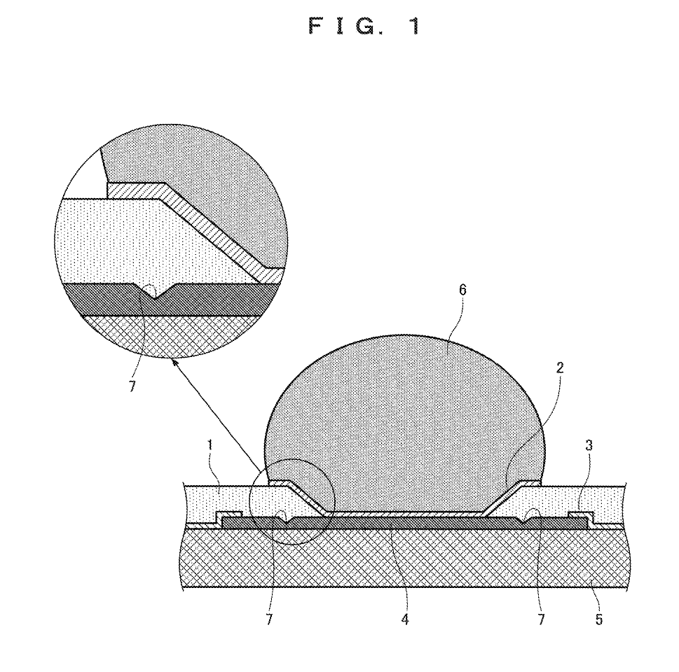

FIG. 1 is a cross-sectional view showing the structure including a bump and the surrounding of the bump of a semiconductor device according to the embodiment. As shown in FIG. 1, the semiconductor device according to the embodiment includes: a silicon substrate 5 which is an example of a substrate; an electrode pad 4 formed on the silicon substrate 5; a protective film 1 which has an opening to expose a part of the electrode pad 4 and covers the surface of the electrode pad 4 around the opening; and a bump 6 which is electrically connected with the electrode pad 4 through the opening of the protective film 1 and is an example of an external connection end having a part exposed to the outside within the range of the area of the electrode pad 4. Probe marks 7 are formed on the surface of the electrode pad 4 by a probe brought into contact with the electrode pad 4 for electrical characteristic inspection. The probe marks 7 are covered by the protective film 1.

The following will specifically describe the semiconductor device according to the embodiment.

The silicon substrate 5 has a circuit region (not shown) which is electrically connected with the electrode pad 4 in a predetermined position of the silicone substrate 5. The electrode pad 4 may be made of, for example, aluminum.

A first protective film 3 is formed on the silicon substrate 5 to protect a chip surface by covering the silicon substrate 5 and the periphery of the electrode pad 4. Therefore, the periphery of the electrode pad 4 is covered by the first protective film 3, so that the center and a region therearound excluding the periphery are exposed from the first protective film 3. The first protective film 3 thus has a first aperture to expose a part of the electrode pad 4. The first protective film 3 may be made of, for example, silicon nitride (Si₃N₄). The first protective film 3 does not necessarily have to cover the entire periphery of the electrode pad 4 as long as the surface of the silicon substrate 5 excluding the area of the electrode pad 4 is covered.

The probe marks 7 are formed on the surface of the region of the electrode pad 4 exposed from the first protective film 3 by the probe contact for electrical characteristic inspection on the circuit region of the silicon substrate 5.

The second protective film 1 has a second aperture which partly exposes the surface of the electrode pad 4 exposed from the first protective film 3, and covers the first protective film 3 and the surface of the electrode pad 4 ranging from the peripheral edge of the second aperture to the first protective film 3. Therefore, the surface of the silicon substrate 5 excluding the area of the electrode pad 4 and the periphery of the electrode pad 4 are doubly coated with the first protective film 3 and the second protective film 1. The second protective film 1 may be made of, for example, polyimide. Further, the second protective film 1 is formed so as to cover the probe marks 7.

A region around the second aperture of the second protective film 1 can take any shape. As shown in the drawings, the region may be inclined such that the second protective film 1 decreases in thickness toward the exposed region of the electrode pad 4. The inclination strengthens the bond between the bump 6 and an under barrier metal 2 formed ranging from the exposed region of the electrode pad 4 to the second protective film 1 therearound.

The area of the electrode pad 4 to be exposed from the second protective film 1 has to have at least a certain value to set connection resistance between the bump 6 and the electrode pad 4 at a predetermined value or less. Therefore, the electrical characteristic inspection is desirably carried out with the probe contact concentrated in the vicinity of the periphery of the electrode pad 4 to obtain an area required for setting the connection resistance between the bump 6 and the electrode pad 4 at the predetermined value or less when a region of the electrode pad 4 containing no probe marks 7 is exposed from the second protective film 1. For example, in the case where the center of the second aperture of the second protective film 1 is aligned with the center of the electrode pad 4, it is obvious that the diameter of the second aperture is smaller, as the probe marks 7 are formed closer to the center of the electrode pad 4. Size reduction in the diameter of the second aperture is supposed to increase the connection resistance between the bump 6 and the electrode pad 4. Therefore, the diameter of the first aperture of the first protective film 3 is preferably at least half the diameter of the electrode pad 4 to reduce the connection resistance between the bump 6 and the electrode pad 4 while maintaining connection reliability. In other words, the probe mark 7 is preferably formed in a region of the electrode pad 4 ranging from a point corresponding to half a distance of the center to external end of the electrode pad 4 to the external end of the electrode pad 4.

The under barrier metal 2 is formed on the surface of the region of the electrode pad 4 exposed from the second protective film 1 and on the second protective film 1 around the region. The bump 6 is formed as an external connection terminal on the under barrier metal 2. The under barrier metal 2 may be formed by sputtering, vapor deposition, or plating.

In the semiconductor device according to the embodiment, as shown in FIG. 1, the thickness of the second protective film 1 is set such that the probe marks 7 (including parts on the electrode pad raised by the probe marks: the same applies to the following) are entirely covered by the second protective film 1. This reduces or prevents effects of the probe marks 7 on the shapes of the under barrier metal 2 and the bump 6 even in the state where the under barrier metal 2 is formed over the probe marks 7 as shown in FIG. 1. Hence, the bond strength between the electrode pad 4 and the bump 6 is secured through the under barrier metal 2, thereby reducing or preventing poor connection. Further, the shape of the bump can be suppressed or prevented from being varied, thereby improving the connection reliability of the bump 6 and the like. Incidentally, the connection reliability of the bump 6 and the like can be improved without an increase in the area of the electrode pad 4.

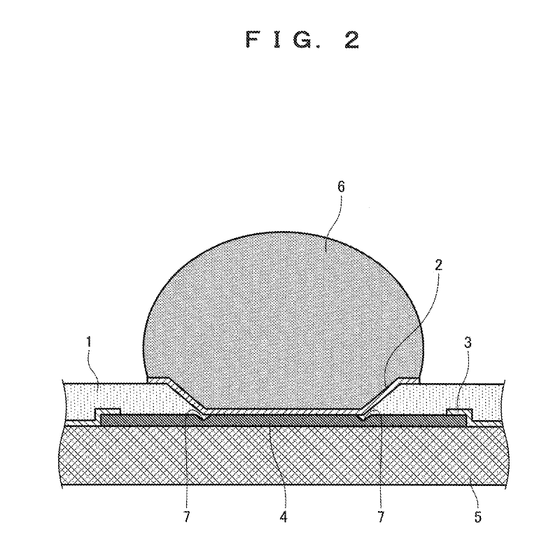

Even in the case where the probe marks 7 are positioned directly under the ends of the second aperture of the second protective film 1 as shown in FIG. 2, the connection reliability of the bump 6 and the like can be improved as long as the probe marks 7 are entirely covered by the second protective film 1.

Moreover, in the case where the probe marks 7 are positioned directly under the ends of the second aperture of the second protective film 1, the same effects as in the state of FIG. 2 can be expected even if the probe marks 7 are incompletely covered by the second protective film 1 and partly exposed from the second aperture of the second protective film 1.

The following will describe the shape of the second aperture of the second protective film 1 and the positions of the probe marks 7 with reference to FIGS. 3 to 11. FIGS. 3 to 11 are planar views each illustrating the shape of aperture of the second protective film and the positions of the probe marks 7 in the semiconductor device according to the embodiment.

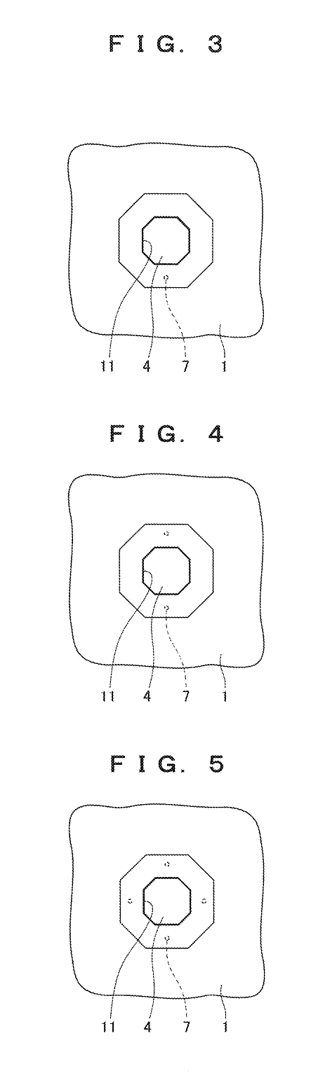

FIGS. 3 to 5 show that the electrode pad 4 and a second aperture 11 of the second protective film 1 are both octagonally-shaped. FIG. 4 shows that the second aperture 11 of the second protective film 1 is formed between the two probe marks 7. FIG. 5 shows that the second aperture 11 of the second protective film 1 is surrounded by the four probe marks 7.

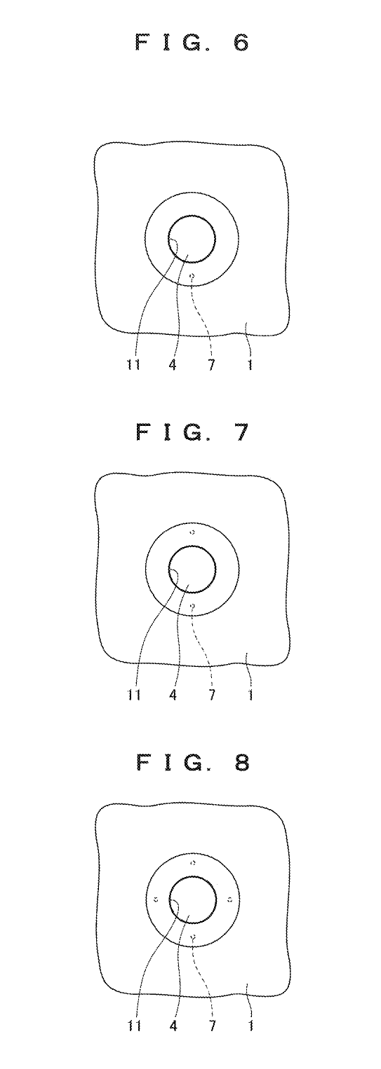

FIGS. 6 to 8 show that the electrode pad 4 and the second aperture 11 of the second protective film 1 are both circular. FIG. 7 shows that the second aperture 11 of the second protective film 1 is formed between the two probe marks 7. FIG. 8 shows that the second aperture 11 of the second protective film 1 is surrounded by the four probe marks 7.

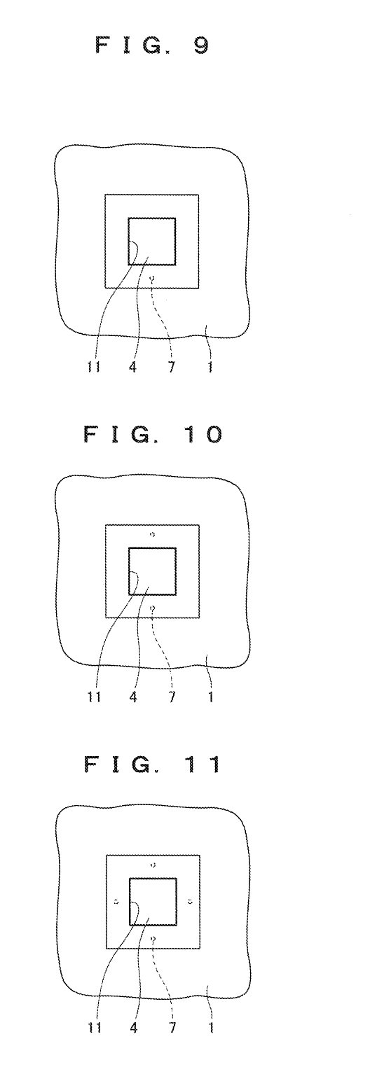

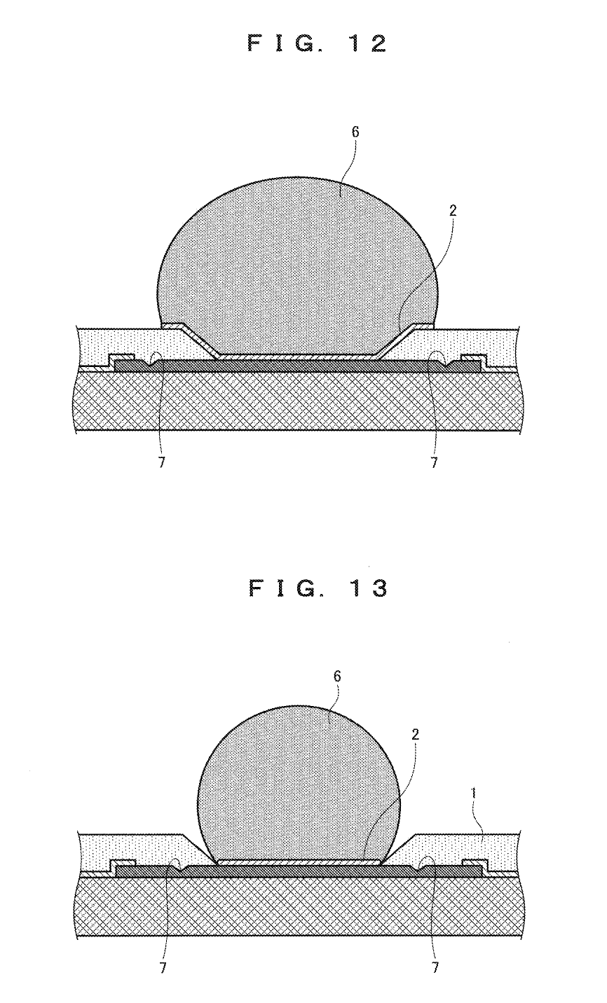

FIGS. 9 to 11 show that the electrode pad 4 and the second aperture 11 of the second protective film 1 are both quadrangular. FIG. 10 shows that the second aperture 11 of the second protective film 1 is formed between the two probe marks 7. FIG. 11 shows that the second aperture 11 of the second protective film 1 is surrounded by the four probe marks 7.

Thus, the shapes of the electrode pad 4 and the second aperture 11 of the second protective film 1 and the positions of the probe marks 7 can be varied and are not limited to those in the drawings.

The following will describe other examples of the structure including the bump and the surrounding of the bump of the semiconductor device according to the embodiment with reference to FIGS. 12 and 13.

FIG. 12 is a cross-sectional view illustrating the structure including the bump 6 formed only in the region containing no probe marks 7 and the surrounding of the bump.

As shown in FIG. 12, the under barrier metal 2 and the bump 6 may be formed inside the probe marks 7 to further reduce effects of the probe marks 7 on the under barrier metal 2 and the bump 6.

In this configuration, poor connection of the bump 6 is not caused by the probe marks 7 since the probe marks 7 are not formed below the formation region of the under barrier metal 2 and the bump 6.

Moreover, even if the heights of the parts on the electrode pad raised by the probe marks exceed the thickness of the second protective film 1, shape defects do not occur on the under barrier metal 2 or the bump 6 since the probe marks 7 are not formed below the formation region of the under barrier metal 2 and the bump 6, thereby preventing poor connection of the bump 6 from being caused by the probe marks 7. Further, no contact is made between the parts on the electrode pad 4 raised by the probe marks 7 and the under barrier metal 2 since the probe marks 7 are not formed below the formation region of the under barrier metal 2 and the bump 6. Therefore, even in the case where the depth of the probe mark 7 reaches the underlayer of the electrode pad 4, metal diffusion from the under barrier metal 2 to the underlayer of the electrode pad 4 can be prevented.

Thus, the under barrier metal 2 is not formed above the probe marks 7 or the probe marks 7 are formed outside the formation region of the bump 6 and the under barrier metal 2, so that poor connection of the bump can be prevented.

FIG. 13 is a cross-sectional view illustrating the structure including the bump 6 formed only in the region of the second aperture of the second protective film 1 and the surrounding of the bump.

As illustrated in FIG. 13, the under barrier metal 2 may be formed so as to fit in the second aperture of the second protective film 1 and the bump 6 may be formed thereon as long as the bump can be large enough to adequately ensure electrical and mechanical connection between the semiconductor chip and the resin substrate in the region of the second aperture of the second protective film 1.

Thus, when the under barrier metal 2 is formed only on the surface of the region of the electrode pad 4 exposed from the second protective film 1 and the bump 6 is formed thereon, the under barrier metal 2 and the bump 6 can be formed without being affected by the probe marks 7 at all.

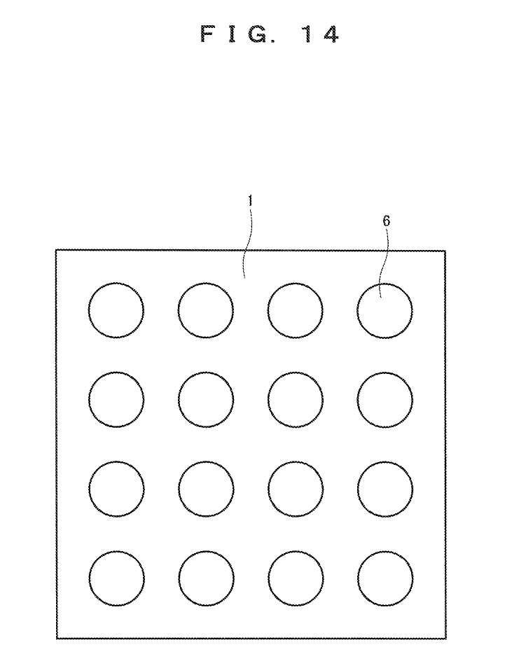

FIG. 14 is a planar view illustrating the bumps arranged in a grid-like pattern of the semiconductor device according to the embodiment. A plurality of bumps 6 can be formed as external connection terminals in the semiconductor device. For example, as shown in FIG. 14, the plurality of bumps 6 may be arranged in a matrix or grid-like pattern.

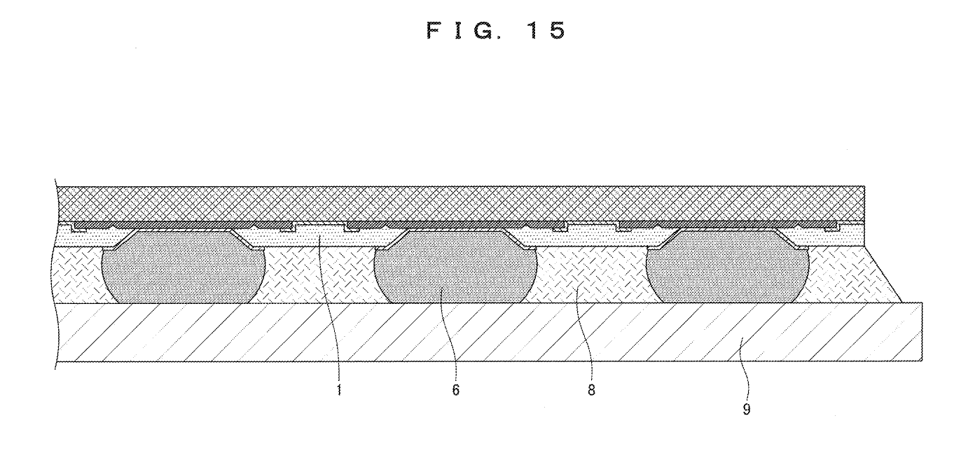

The following will describe a semiconductor device unit according to the embodiment. FIG. 15 is a cross sectional view showing the configuration of the principal part of the semiconductor device unit according to the embodiment.

As illustrated in FIG. 15, the semiconductor device including the bumps 6 may be flip-chip mounted on a mounting substrate 9, and the undersurface of the semiconductor device may be sealed by an underfill 8 to configure a semiconductor device unit. With this configuration, a high-density semiconductor device unit can be realized. Further, as described above, the reliability of the semiconductor device can be easily improved by reducing or preventing poor connection of the bumps without expanding the region of the electrode pad.

According to the above-described embodiment, unlike in, for example, the semiconductor device of Patent Literature 1, a complex process and an area for forming a rewiring layer are not necessary, so that the reliability of the semiconductor device can be improved by reducing or preventing poor connection of the bumps without expanding the region of the electrode pad by means of the simple structure and process.

In other words, according to the embodiment, the second protective film 1 is formed over the formation region of the probe marks 7. Thus, the shapes of the probe marks 7 can be prevented or suppressed from affecting the shapes of the under barrier metal 2 and the bumps 6.

Further, the probe marks 7 are not in direct contact with the under barrier metal 2. Thus, even in the case where the depth of the probe mark 7 reaches the underlayer of the electrode pad 4, metal diffusion cannot occur between the under barrier metal 2 and the underlayer of the electrode pad 4. Hence, the bond reliability can be suppressed from being reduced.

Furthermore, according to the structure including the bump and its surrounding in FIGS. 12 and 13, even in the case where the heights of the parts on the electrode pad 4 raised by the probe marks 7 exceed the thickness of the second protective film 1, metal diffusion cannot occur between the under barrier metal 2 and the underlayer of the electrode pad 4 even when the depth of the probe mark 7 reaches the underlayer of the electrode pad 4. This is because the under barrier metal 2 and the bump 6 are not present above the formation region of the probe marks 7.

According to the embodiment, unlike in the semiconductor device of Patent Literature 2, it is not necessary to provide an electrode for probe inspection in addition to an electrode for bump formation, the electrode for probe inspection being connected to the electrode for bump formation. Thus, according to the embodiment, poor connection of the bump can be reduced or prevented while avoiding effects of the probe marks by a simple process within a limited space of a reduced chip area. Hence, the reliability of the semiconductor device can be improved. Such advantages will have become increasingly apparent with reduction in the pitch and size of the bump.

The following will describe an example of a semiconductor device production method according to the embodiment with reference to FIGS. 16 to 20. FIGS. 16 to 20 each illustrate a part of the steps of producing the semiconductor device according to the embodiment.

First, a circuit region is formed on the silicon substrate 5. Next, the electrode pad 4 made of, for example, aluminum is formed on the surface of the silicon substrate 5 where the bump is to be formed. The electrode pad 4 is electrically connected to the circuit region. Thereafter, the first protective film 3 made of, for example, silicon nitride (Si₃N₄) is formed so as to cover the surface of the silicon substrate 5 where the bump is to be formed and the electrode pad 4.

Subsequently, as shown in FIG. 16, the first protective film 3 is selectively removed to form the first aperture of the first protective film 3 which exposes a part of the electrode pad 4.

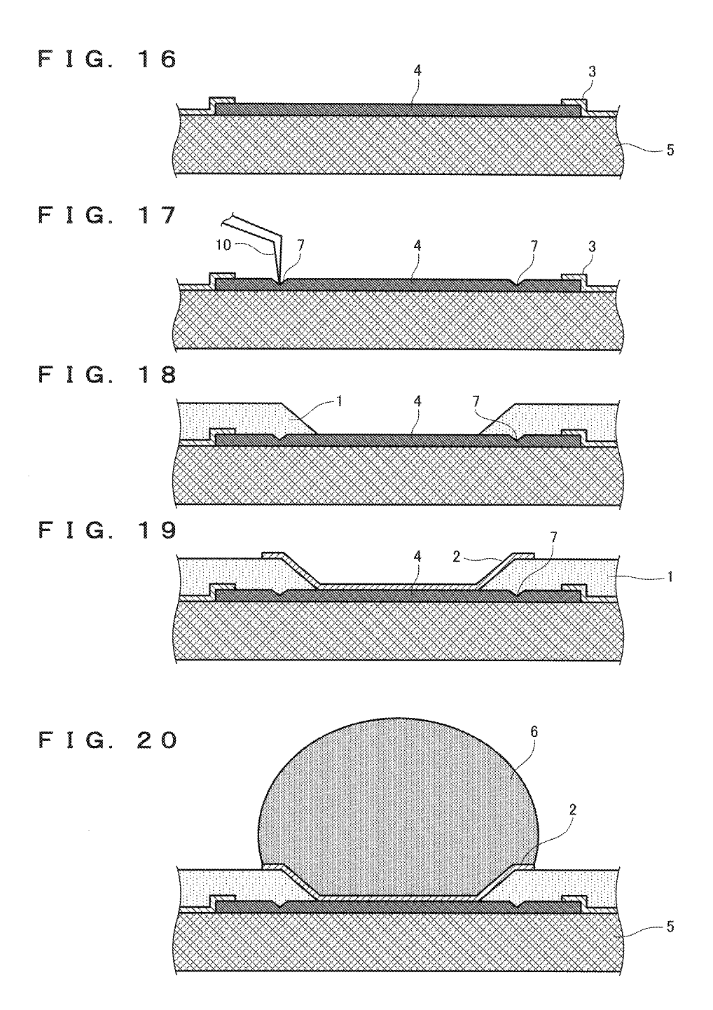

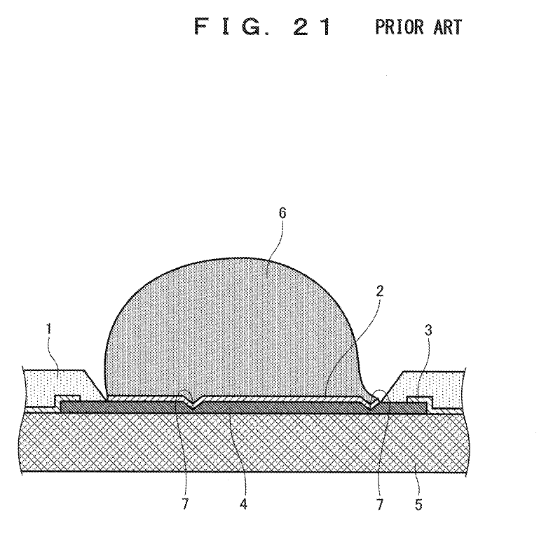

As shown in FIG. 17, electrical characteristic inspection is performed on the circuit region formed on the silicon substrate 5 by bringing a probe 10 into contact with the electrode pad 4. As a result, the probe mark 7 is formed on the electrode pad 4. At this point, the electrical characteristic inspection may be performed more than once to form multiple probe marks 7 on the electrode pad 4.

Preferably, the probe 10 is brought into contact with the vicinity of the peripheral edge of the first aperture of the first protective film 3 or the vicinity of the peripheral edge of the electrode pad 4 within a part of the electrode pad 4 exposed from the first protective film 3 during the electrical characteristic inspection. Thus, the bond area of the electrode pad 4 and the under barrier metal 2 can be expanded, further expanding the bond area of the under barrier metal 2 and the bump 6.

Probes conforming to various specifications may be applied to the probe 10. For example, vertical needle type probes are most preferably used since the area of the probe mark 7 can be reduced. The probe marks 7 are formed in different shapes (depths, widths and so on) on the electrode pad 4. For example, the probe mark 7 with a diameter of about 3 μm and a depth of about 0.5 μm is formed in the first aperture of the first protective film 3 with a diameter of about 50 μm.

After the electrical characteristic inspection, the second protective film 1 made of, for example, polyimide is evenly applied, using a spinner, on the electrode pad 4 and the first protective film 3, that is, over the surface of the silicon substrate 5 containing the region of the electrode pad 4 where the bump is to be formed. Subsequently, prebake is performed (at 70° C. for 50 seconds, at 90° C. for 50 seconds, and at 105° C. for 110 seconds) and then exposure is performed to form a pattern for the second aperture with a predetermined shape. Thereafter, pre-development bake (at 80° C. for 50 seconds), and development and cure (at 140° C. for 170 seconds and at 350° C. for 3600 seconds, respectively) are sequentially performed. Through these steps, as shown in the FIG. 18, the second aperture which exposes at least a part of the surface of the electrode pad 4 is formed on the second protective film 1. Therefore, the second protective film 1 covers the surface of the electrode pad 4 excluding the second aperture.

The second aperture of the second protective film 1 has to be formed such that the probe marks 7 formed on the electrode pad 4 by the contact of the probe 10 are covered by the second protective film 1 but are not exposed in the region of the second aperture of the second protective film 1. Therefore, the probe marks 7 have to be positioned so as to be covered by the second protective film 1. The second protective film 1 may be made of, for example, benzoxazole or silicone resin instead of polyimide.

As shown in FIG. 19, the under barrier metal 2 with a thickness of about 1×10⁻³ mm to 7×10⁻³ mm is formed by sputtering, vapor deposition, or the like. A region for the under barrier metal 2 to be formed can be controlled by varying the shape of a resist pattern. FIG. 19 shows that, as in FIG. 1, the under barrier metal 2 is formed over the surface of the region of the electrode pad 4 exposed from the second protective film 1 and the second protective film 1 around the second aperture thereof.

As shown in FIG. 1, even in the case where the under barrier metal 2 is formed above the probe marks 7 so as to cover the probe marks 7, effects of the probe marks 7 on the shapes of the under barrier metal 2 and the bump 6 to be formed thereon are reduced at the stage of forming the second protective film 1, and thus are hardly produced.

As illustrated in FIG. 12, when the under barrier metal 2 is not formed above the probe marks 7, effects of the probe marks 7 on the shapes of the under barrier metal 2 and the bump 6 are further reduced.

Alternatively, as illustrated in FIG. 13, the under barrier metal 2 is formed only within the region of the second aperture of the second protective film 1 and the bump 6 is formed thereon, so that effects of the probe marks 7 can be completely eliminated.

Preferably, the under barrier metal 2 illustrated in FIG. 13 is formed by non-electrolytic plating instead of the above-described sputtering and vapor deposition. In forming the under barrier metal 2 by non-electrolytic plating, an oxide film is removed by soft-etching the surface of the electrode pad 4, zinc particles are precipitated by immersion in a zincate treatment solution, and a nickel film with a thickness of about 5×10⁻³ mm is formed on the electrode pad 4 by immersion in an electroless nickel (Ni) plating solution. Further, flash gold (Au) plating with a thickness of about 5×10⁻⁵ mm may be applied on the nickel film by immersion in an electroless gold (Au) plating solution. When the under barrier metal 2 is formed by plating, the thickness of the under barrier metal 2 can be easily controlled by increasing or decreasing plating time, and thus the region for the under barrier metal 2 to be formed can be controlled.

After forming the under barrier metal 2 at least on the surface of the region of the electrode pad 4 exposed from the second protective film 1, as shown in FIG. 20, the bump 6 is formed as an external connection terminal on the under barrier metal 2. The bump 6 can be formed by ball mounting, plating, dispensing, or the like.

In ball-mounting, for example, a print mask is prepared which is made of a metal plate having a thickness of about 0.02 mm to 0.04 mm and an aperture in a position corresponding to the under barrier metal 2. The surface of the silicon plate 5, on which the bump is to be formed, is entirely covered by the print mask and then flux is printed on the surface of the under barrier metal 2 by a rubber or metal squeegee. Subsequently, a bump material is provided on the under barrier metal 2 with the flux printed thereon by a loading mask having an aperture in a position corresponding to the under barrier metal 2. The silicon substrate 5 with the bump material provided thereon is then heated, so that the bump material is melted and joined to the under barrier meal 2. In the above-described process, the flux printed on the under barrier metal 2 has two principal functions of holding the bump material and removing an oxide film at the time of remelting (reflowing). Therefore, the flux may be rosin or water-soluble flux. Particularly, halogen-free rosin flux is preferable. The bump material is preferably a solder ball made of tin, silver, copper, or the like but may be made of materials having other compositions. The diameter of the bump material is preferably about 0.07 mm to 0.125 mm. In the case where the bump material is not spherical, the average length and width are preferably about 0.07 mm to 0.125 mm, but not limited to these values.

Through the above-described steps, poor connection of the bump is easily reduced or prevented without expanding the region of the electrode pad 4, so that a highly reliable semiconductor device can be realized.

For example, when the semiconductor device thus obtained is flip-chip mounted on a mounting substrate such as a resin substrate, a highly reliable semiconductor device unit can be produced with the protrusion of the bump reduced or prevented.

In the semiconductor device and the semiconductor device unit produced by the foregoing method, the probe marks are not present below the under barrier metal. Thus, effects of the probe marks can be reduced or prevented without expanding the region of the electrode pad. Further, poor connection of the bump can be easily reduced or prevented, so that the reliability of the semiconductor device can be improved.

As described above, according to the embodiment, the probe marks 7 are covered by the second protective film 1, and the under barrier metal 2 and the bump 6 are formed at least on the surface of the region of the electrode pad 4 exposed from the second protective film 1. Thus, the shapes and bond state of the under barrier metal 2 and the bump 6 can be hardly affected by the shapes of the probe marks 7.

In the present embodiment, the under barrier metal is provided between the bump and the electrode pad. However, the under barrier metal may not be provided as long as the bond strength can be obtained between the bump and the electrode pad.

Further, the first protective film may be omitted when the second protective film is made to have the effect of protecting the substrate surface.

In the above explanation, the semiconductor device is formed from the silicon substrate. However, various semiconductor substrates including a gallium nitride substrate may be used instead of the silicon substrate.

### INDUSTRIAL APPLICABILITY

According to the semiconductor device, semiconductor device unit, and semiconductor device production method of the present invention, the reliability of the semiconductor device can be improved by easily reducing or preventing poor connection of the bump without expanding the region of the electrode pad. Particularly, the present invention is useful for a semiconductor device including an under barrier metal, protective film, and bump, a semiconductor device unit including the semiconductor device, and a production method for the semiconductor device.

1. A semiconductor device comprising:
a substrate;
at least one electrode pad formed on the substrate;
a protective film which has an opening to expose a part of a surface of the at least one electrode pad and covers the surface of the at least one electrode pad excluding the opening; and
an external connection terminal which is electrically connected with the at least one electrode pad through the opening of the protective film and has a part exposed outside within an area of the at least one electrode pad, wherein
at least one probe mark is formed on the at least one electrode pad by a probe brought in contact with the at least one electrode pad for electrical characteristic inspection, and
the at least one probe mark is positioned within a region where the protective film is formed or directly under an end of the opening of the protective film and is covered by the protective film.

2. The semiconductor device according to claim 1, wherein the at least one probe mark is formed outside a region where the external connection terminal is formed, as seen in a plan view.

3. The semiconductor device according to claim 1, further comprising:
an under barrier metal which is formed over a surface of the part of the at least one electrode pad exposed from the opening of the protective film and the protective film around the opening or an under barrier metal which is formed only on the surface of the part of the at least one electrode pad exposed from the opening of the protective film, wherein
the external connection terminal is formed on the under barrier terminal.

4. The semiconductor device according to claim 1, wherein the at least one probe mark is formed in the vicinity of a peripheral edge of the at least one electrode pad.

5. The semiconductor device according to claim 1, wherein the at least one probe mark comprises a plurality of probe marks.

6. The semiconductor device according to claim 1, wherein the at least one electrode pad comprises a plurality of electrode pads which are arranged in a matrix pattern.

7. The semiconductor device according to claim 1, wherein the at least one probe mark comprises at least two probe marks, and the opening of the protective film is disposed between the two probe marks, as seen in a plan view.

8. A semiconductor device unit comprising:
a mounting substrate; and
the semiconductor device according to claim 1 which is mounted on the mounting substrate.

9. A semiconductor device production method comprising the steps of:
forming at least one electrode pad on a substrate;
performing electrical characteristic inspection by bringing a probe into contact with the at least one electrode pad;
forming a protective film which has an opening to expose a part of a surface of the at least one electrode pad and covers the surface of the at least one electrode pad excluding the opening; and
forming an external connection terminal which is electrically connected with the at least one electrode pad through the opening of the protective film and has a part exposed outside within an area of the at least one electrode pad, wherein,
in the step of performing the electrical characteristic inspection, at least one probe mark is formed on the at least one electrode pad, and
in the step of forming the protective film, the protective film is formed such that the at least one probe mark is positioned within a region where the protective film is formed or directly under an end of the opening of the protective film and is covered by the protective film.
